(19) United States
(12) Patent Application Publication
(10) Pub. No.: US 2026/0104634 A1
(43) Pub. Date: Apr. 16, 2026

(54) MASK DATA PREPARATION METHOD, SEMICONDUCTOR CHIP MANUFACTURING METHOD USING THE SAME, AND COMPUTING DEVICE

(71) Applicant: Samsung Electronics Co., Ltd., Suwon-si (KR)

(72) Inventors: Hyunjae LEE, Suwon-si (KR); Yun-Ju HAN, Suwon-si (KR)

(73) Assignee: Samsung Electronics Co., Ltd., Suwon-si (KR)

(21) Appl. No.: 19/170,131

(22) Filed: Apr. 4, 2025

(30) Foreign Application Priority Data
Oct. 15, 2024 (KR) 10-2024-0139972

(51) Int. Cl. G03F 1/22; G03F 7/00; G03F 7/20

(52) U.S. Cl. CPC G03F 1/22; G03F 7/2026; G03F 7/70033; G03F 7/70433

(57) ABSTRACT

Provided is a mask data preparation method, including generating shot-level pattern data including a first layout and a second layout, in which the first layout and the second layout are located across a boundary line between a first shot-data region and a second shot-data region adjacent to the first shot-data region, generating a first correction layout and a first plurality of auxiliary patterns associated with the first layout based on the shot-level pattern data, generating a second correction layout and a second plurality of auxiliary patterns associated with the second layout based on the shot-level pattern data, generating corrected shot-level pattern data based on the first correction layout, the first plurality of auxiliary patterns, the second correction layout, and the second plurality of auxiliary patterns, extracting a first mask data based on the corrected shot-level pattern data, and extracting based on the corrected shot-level pattern data a second mask data.

### CROSS-REFERENCE TO RELATED APPLICATION

This application claims priority to Korean Patent Application No. 10-2024-0139972, filed in the Korean Intellectual Property Office on Oct. 15, 2024, the entire contents of which are hereby incorporated by reference.

### BACKGROUND

### Technical Field

The present disclosure relates to mask data preparation methods, semiconductor chip manufacturing methods using the same, and computing devices.

### Description of Related Art

In general, circuit patterns are formed on wafers through a photolithography process and a subsequent etching process in the manufacturing process of semiconductor devices. At this time, each circuit pattern is transferred onto the wafer in the photolithography process using a mask according to a pre-designed layout. The circuit patterns formed across a plurality of shot regions on the wafer may be difficult to transfer accurately due to optical proximity effect (OPE). The optical proximity effect may cause pattern distortions at boundaries between the shot regions, and the more minute the spacing between adjacent patterns, the more pronounced the effect may be.

In particular, pattern errors due to optical proximity effect are likely to occur at the boundaries of the shot regions, and these errors may cause problems that make it difficult to secure additional process margins. Accordingly, for the pattern located at the boundary of the shot region, an appropriate solution is required to minimize or reduce pattern errors due to the optical proximity effect.

### SUMMARY

In order to solve or improve upon one or more problems (e.g., the problems described above and/or other problems not explicitly described herein), the present disclosure provides mask data preparation methods, semiconductor chip manufacturing methods using the same, and computing devices.

Objects to be achieved by the present disclosure are not limited to the objects described above, and other objects not mentioned can be clearly understood by those skilled in the art from the description of the present disclosure below.

According to one or more example embodiments of the disclosure, a mask data preparation method may include generating shot-level pattern data including a first layout and a second layout, in which the first layout and the second layout may be located across a boundary line between a first shot-data region and a second shot-data region adjacent to the first shot-data region, generating a first correction layout and a first plurality of auxiliary patterns associated with the first layout based on the shot-level pattern data, generating a second correction layout and a second plurality of auxiliary patterns associated with the second layout based on the shot-level pattern data, generating corrected shot-level pattern data based on the first correction layout, the first plurality of auxiliary patterns, the second correction layout, and the second plurality of auxiliary patterns, extracting a first mask data based on the corrected shot-level pattern data, and extracting based on the corrected shot-level pattern data a second mask data.

According to one or more example embodiments of the disclosure, a semiconductor chip manufacturing method may include generating shot-level pattern data including a first layout and a second layout, in which the first layout and the second layout may be on a boundary line between a first shot-data region and a second shot-data region adjacent to the first shot-data region, generating a first correction layout and a first plurality of auxiliary patterns associated with the first layout based on the shot-level pattern data, generating a second correction layout and a second plurality of auxiliary patterns associated with the second layout based on the shot-level pattern data, generating corrected shot-level pattern data based on the first correction layout, the first plurality of auxiliary patterns, the second correction layout, and the second plurality of auxiliary patterns, extracting a first mask data based on the corrected shot-level pattern data, extracting a second mask data based on the corrected shot-level pattern data, manufacturing a first mask based on the first mask data, manufacturing a second mask based on the second mask data, forming a first partial transfer pattern on a wafer using the first mask, and forming a second partial transfer pattern on the wafer using the second mask.

According to one or more example embodiments of the disclosure, a computing device that performs mask data preparation may include a non-transitory memory configured to store at least one instruction, and a processor including a plurality of processing cores, in which the processor may be configured to execute the at least one instruction to generate shot-level pattern data including a first layout and a second layout, in which the first layout and the second layout located across a boundary line between a first shot-data region and a second shot-data region adjacent to the first shot-data region, generate a first correction layout and a first plurality of auxiliary patterns associated with the first layout based on the shot-level pattern data, generate a second correction layout and a second plurality of auxiliary patterns associated with the second layout based on the shot-level pattern data,, generate corrected shot-level pattern data based on the first correction layout, the first plurality of auxiliary patterns, the second correction layout, and the second plurality of auxiliary patterns, extract a first mask data based on the corrected shot-level pattern data, and extract a second mask data based on the corrected shot-level pattern data.

According to one or more example embodiments of the disclosure, a mask data preparation method may include generating shot-level pattern data including layouts, the layouts including a first layout and a second layout located across a boundary line between a first shot-data region and a second shot-data region adjacent to the first shot-data region, generating correction layouts and auxiliary patterns associated with respective layouts based on the shot-level pattern data, generating corrected shot-level pattern data based on the correction layouts and the associated auxiliary patterns, extracting mask data based on the corrected shot-level pattern data, the mask data including a plurality of masks associated with each layout of the layouts. The method may further include controlling a photolithography device to manufacture at least one of the plurality of masks.

According to various example embodiments of the present disclosure, by merging a plurality of pieces of layout pattern data corresponding to a plurality of dies associated with a shot boundary line to process the OPC operation and the SRAF application in batch, it is possible to minimize or reduce the mismatch problem of pattern transfer that may occur in the boundary region and/or also increase the transfer accuracy.

According to various example embodiments of the present disclosure, in the case of a layout spanning a boundary portion between shot regions, instead of individually processing design layout data for each shot region, a plurality of pieces of layout pattern data corresponding to a plurality of dies associated with the shot boundary line may be merged so that the OPC operation and the SRAF application may be processed in batch. Accordingly, the time and effort, processing power, resources, etc., required for processing for each shot region may be reduced, and/or a turnaround time (TAT) may be reduced or effectively shortened.

According to various example embodiments of the present disclosure, rather than extracting specific attributes of all electrical signals transmitted in the layout pattern in the full-chip layout, by simply determining whether or not the electric signals transmitted between adjacent layout patterns are the same and using the result for the retargeting operation, the processing resources and/or memory resources required for retargeting operations can be reduced and may be, e.g., significantly reduced.

Various and beneficial advantages and effects of the present disclosure are not limited to those described above, and can be more easily understood in the course of describing specific example embodiments of the present disclosure.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIG. 1 is a block diagram illustrating a computing system for performing a mask data preparation method according to some example embodiments;

FIG. 2 is a flowchart provided to explain a semiconductor chip manufacturing method according to some example embodiments;

FIG. 3 is a plan view illustrating a wafer and shot regions formed on the wafer according to some example embodiments;

FIG. 4 is an enlarged view of a first shot region and a second shot region of FIG. 3;

FIG. 5 is a flowchart provided to explain an operation S40 of FIG. 2 in detail.

FIG. 6 is a diagram illustrating an example of first layout pattern data and second layout pattern data according to some example embodiments;

FIG. 7 is a diagram illustrating an example of shot-level pattern data according to some example embodiments;

FIG. 8 is a diagram illustrating an example of shot-level pattern data subjected to an OPC operation according to some example embodiments;

FIG. 9 is a diagram illustrating an example of corrected shot-level pattern data subjected to an SRAF operation according to some example embodiments;

FIG. 10 is a diagram illustrating an example of corrected shot-level pattern data according to some example embodiments;

FIG. 11 is a diagram illustrating an example of corrected shot-level pattern data including an overlapping region according to some example embodiments;

FIG. 12 is a diagram illustrating an example of first mask data according to some example embodiments;

FIG. 13 is a diagram illustrating an example of second mask data according to some example embodiments;

FIGS. 14 and 15 are diagrams provided to explain a process of transferring a circuit pattern onto a wafer by using a first mask and a second mask according to some example embodiments; and

FIG. 16 is a diagram illustrating an example of a circuit pattern transferred onto a wafer according to some example embodiments.

### DETAILED DESCRIPTION

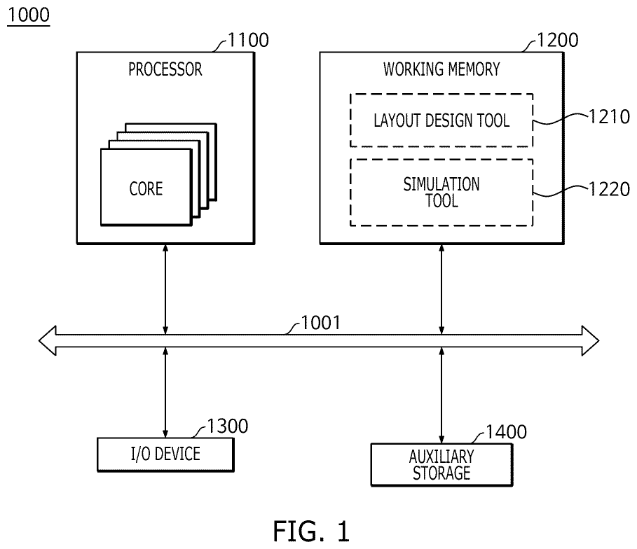

Hereinafter, various embodiments of the present disclosure will be described with reference to FIGS. 1 to 16. The same reference numerals may refer to the same components throughout the description.

FIG. 1 is a block diagram illustrating a computing system 1000 for performing a mask data preparation method according to some example embodiments. Referring to FIG. 1, the computing system 1000 may include at least one processor 1100, a working memory 1200, an input/output device 1300, and an auxiliary storage device 1400, which are connected to a system bus 1001. For example, the at least one processor 1100 and the working memory 1200 may be referred to as a computing device.

The computing system 1000 may be a dedicated device for generating/correcting a layout of a semiconductor chip, or may include a dedicated device for performing a semiconductor design including the same. For example, the computing system 1000 may include various design and verification simulation programs.

In the computing system 1000, the processor 1100, the working memory 1200, the input/output device 1300, and the auxiliary storage device 1400 may be electrically connected to each other through the system bus 1001 and may exchange data with each other.

The processor 1100 may be implemented to execute at least one instruction. For example, the processor 1100 may be implemented to execute software (application program, operating system, device drivers) to be executed on the computing system 1000. The processor 1100 may execute an operating system loaded into the working memory 1200. The processor 1100 may execute various application programs to be driven based on the operating system.

The processor 1100 may be a central processing unit (CPU), a microprocessor, an application processor (AP), or any similar processing device. Meanwhile, the processor 1100 may include a plurality of processing cores. The plurality of processing cores may execute instructions in parallel to quickly execute various application programs.

The working memory 1200 may include a volatile memory such as dynamic random access memory (DRAM), static random access memory (SRAM), etc., and/or non-volatile memory such as flash memory, phase change random access memory (PRAM), resistance random access memory (RAM), ferroelectric random access memory (FRAM), etc.

The working memory 1200 may be implemented to store at least one instruction to be executed in the processor 1100. For example, an operating system or application programs may be loaded into the working memory 1200, and various input/output operations of the computing system 1000 may be supported by the operating system. Similarly, application programs selected by a user or for providing basic services may be loaded into the working memory 1200. In particular, a layout design tool 1210 for semiconductor design or a simulation tool 1220 for mask data preparation such as layout pattern correction, etc., may be loaded from the auxiliary storage device 1400 into the working memory 1200.

The layout design tool 1210 may perform an operation of changing a design rule (DR) or changing shapes and positions of specific layout patterns differently from those defined by the design rule. For example, the layout design tool 1210 may change a design rule related to spacing of distances between adjacent layout patterns, spacing between specific layout layers, etc.

For the layout pattern, the simulation tool 1220 may perform a retargeting operation, an Optical Proximity Correction (OPC) operation, an operation of applying a Sub-Resolution Assistance Feature (SRAF), etc. For example, the retargeting operation may include an operation of changing the layout based on the changed design rule. Additionally, the retargeting operation may include correcting the shape and position of metal patterns by applying bias to upper and lower metal patterns to reflect errors caused by the optical proximity effect in the photolithography process. In addition, the OPC operation may include an operation of correcting the layout pattern to any one of a plurality of OPC shapes according to conditions. The SRAF application operation may include an operation of correcting the shape and position of a transferred pattern according to the optical proximity effect by using fine patterns that are not transferred.

The input/output device 1300 may control user input and output from user interface devices. For example, the input/output device 1300 may include an input means such as a keyboard, a keypad, a mouse, a touch screen, etc. to receive information from a designer.

Using the input/output device 1300, the designer of the layout may receive or input information on semiconductor regions or data paths requiring adjusted operating characteristics. In addition, the input/output device 1300 may be provided with an output means such as a printer, a display, etc. to display the process and results of processing the layout design tool 1210 or the simulation tool 1220.

The auxiliary storage device 1400 may be provided as a storage medium of the computing system 1000. The auxiliary storage device 1400 may store application programs, OS images, and various types of data. The auxiliary storage device 1400 may be provided in the form of a large-capacity storage device such as a memory card (MMC, eMMC, SD, Micro SD, etc.), a Hard Disk Drive (HDD), a Solid State Drive (SSD), etc.

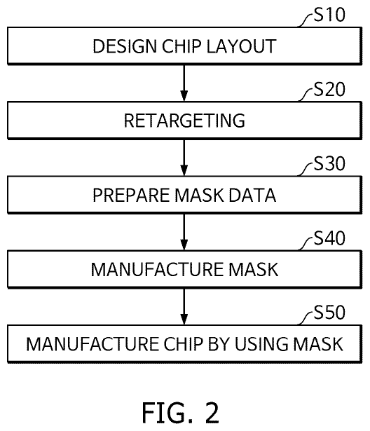

FIG. 2 is a flowchart provided to explain a semiconductor chip manufacturing method according to some example embodiments. Some operations (e.g., S10 to S40) of the semiconductor chip manufacturing method of FIG. 2 may be performed using the computing system 1000 or the computing device of FIG. 1. In addition, some other operations (e.g., S50) of the semiconductor chip manufacturing method may be performed using a photolithography device, etc. In one or more example embodiments, the photolithography device used in the chip manufacturing process S50 using a mask may include High-NA EUV equipment, but the disclosure is not limited thereto.

To manufacture a semiconductor chip, patterns (e.g., circuit patterns) that configure the semiconductor chip are required. The patterns of semiconductor chip may be formed through a process of transferring patterns on a mask onto a substrate such as a wafer through the photolithography process.

To this end, a layout corresponding to the circuit pattern of the semiconductor chip to be formed on the wafer may be designed, at S10. The layout (‘design layout’) may be a set of a plurality of layout patterns for implementing a logically completed semiconductor integrated circuit on the wafer.

The layout is a physical representation provided for the transfer of a circuit designed for the semiconductor chip onto the wafer, and may include a plurality of patterns. For example, the layout may include data such as contour position information (e.g., contour coordinate values) that may specify the position and shape of the plurality of layout patterns. That is, the layout may be provided in a layout pattern data format including the layout contour position information. The plurality of layout patterns may include repeating patterns of same shape, and the plurality of layout patterns may be provided in the form of a combination of polygons such as triangles or rectangles.

The layout may be designed based on predetermined (or, alternatively, selected, or desired) design rules. The design rules may include restrictions on circuit spacing, pattern size, shape, position, etc. The layout may be designed in units of dies on the wafer. For example, the layout pattern data may include information such as position information related to a design layout pattern of a die unit.

A retargeting operation may be performed on the design layout, at S20. The retargeting operation may include an operation of correcting the positions of layout patterns by reflecting errors due to optical proximity effect of the design layout.

A mask data preparation (MDP) operation may be performed on the retargeted layout, at S30. The mask data preparation (MDP) operation may include an OPC operation and a fracturing operation.

The OPC operation may be performed on the retargeted layout. The OPC operation may include changing the shape of layout patterns included in the design layout by reflecting the errors due to optical proximity effect. Although it is illustrated herein that the OPC operation is an operation of changing the shape of the layout pattern, and the retargeting operation is an operation of changing the position of the layout pattern, it is understandable that the retargeting operation and the OPC operation may be merged into an operation of correcting the position and shape of the layout pattern by reflecting errors due to optical proximity effect.

As the layout pattern becomes finer, the optical proximity effect may occur due to the influence between neighboring layout patterns during the photolithography process, in which case pattern distortion due to the occurrence of the optical proximity effect may be corrected by performing the OPC operation.

The OPC operation may include an operation of expanding the overall size of the layout patterns of the design layout and processing a corner portion. The OPC operation may include an operation of moving the edges of each layout pattern or merging additional polygons. By the OPC operation, a pattern distortion phenomenon pattern due to diffraction and interference of light generated during photolithography may be corrected, and errors due to pattern density may be corrected. Additionally, after the OPC operation, an optical proximity correction verification operation may be further performed.

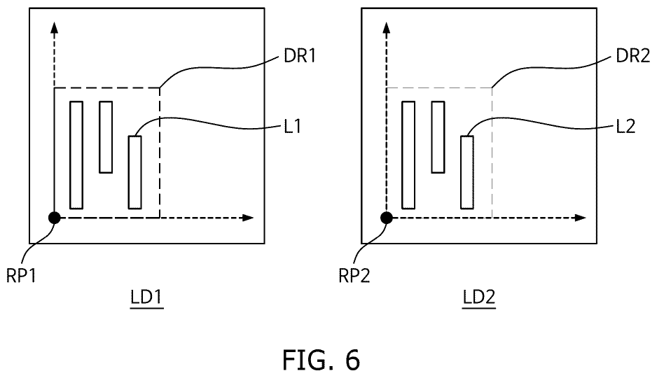

The layout pattern data of the die unit may be divided into a plurality of shot regions and go through the photolithography process, in which the layout pattern data may include a layout pattern crossing a boundary line between the shot regions. In order to increase transfer accuracy of the layout patterns in the boundary lines, instead of individually processing correction operations (e.g., OPC operation and SRAF application) for each shot region, a plurality of pieces of layout pattern data of die units including layout patterns that share the same boundary line may be merged so that the correction operations may be processed in batch. Through this, the continuity of the layout pattern at the boundary line may be improved and/or ensured, and/or the transfer accuracy may be improved. This will be described in detail below with reference to FIGS. 6 to 11.

The fracturing operation may be performed on the corrected layout. The fracturing operation may include an operation of dividing the designed full-chip layout into polygons that conform to, for example, electron beam shapes. This is because when performing the electron beam photolithography process, the shape of the electron beam may be limited to a certain polygonal shape such as a rectangle or a triangle.

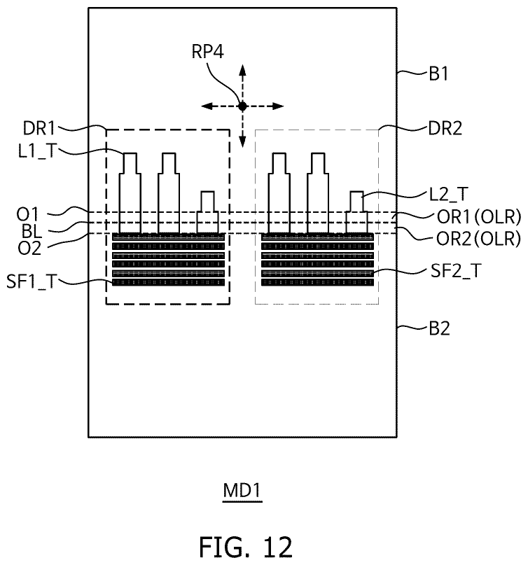

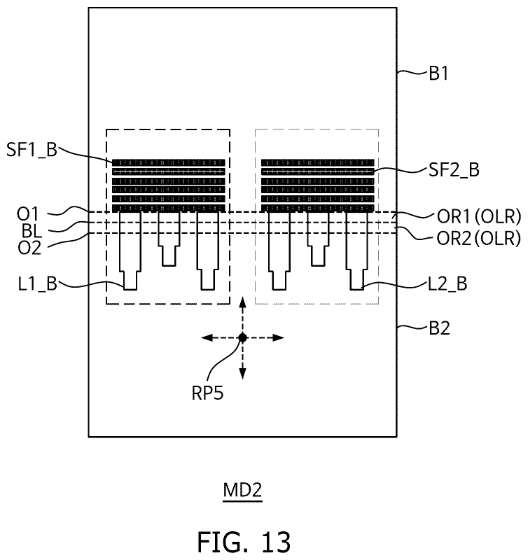

After the layout pattern data of the plurality of die units including the layout patterns sharing the same boundary line is merged and the OPC operation and the SRAF application are processed in batch, the merged layout pattern data may be divided according to each shot region. This will be described in detail below with reference to FIGS. 12 and 13.

The final layout data, which has been corrected by the retargeting operation and the OPC operation and fractured, may be transmitted to the photolithography device for manufacturing a mask to be used in the photolithography process, such as a photomask and/or an electron beam mask.

Using the layout transmitted to the photolithography device, a mask may be manufactured, at S40. For example, the mask may be manufactured by performing the photolithography process on a mask substrate using the corrected layout data. Additionally, after the photolithography process, the mask may be formed as a series of processes such as development, etching, cleaning, baking, etc. are additionally performed.

A semiconductor chip may be manufactured using the manufactured mask, at S50. For example, the semiconductor chip may be manufactured by performing the photolithography process using the mask. The semiconductor chip may include a volatile memory such as dynamic random access memory (DRAM), static random access memory (SRAM), etc., or a non-volatile memory such as flash memory, etc. Additionally, the semiconductor chip may include a logic semiconductor device such as micro-processor, for example, a central processing unit (CPU), a controller, an application specific integrated circuit (ASIC), etc. The semiconductor chip may be finally manufactured as the deposition process, the etching process, the ion process, the cleaning process, etc. are additionally performed in addition to the photolithography process.

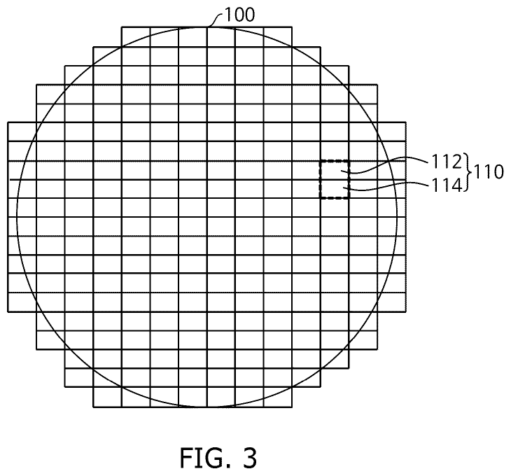

FIG. 3 is a plan view illustrating a wafer 100 and shot regions 110 formed on the wafer according to some example embodiments. Referring to FIG. 3, the wafer 100 may be divided into a plurality of shot regions 110, and the wafer 100 may be a substrate on which the semiconductor device is formed. For example, the wafer 100 may include various materials such as silicon (Si), gallium arsenide (GaAs), or silicon carbide (SiC), but is not limited thereto.

The shot regions 110 may represent a physical range in which the photolithography device transfers patterns in one shot during the semiconductor manufacturing process. The plurality of shot regions 110 may be disposed across the entire wafer 100. For example, the shot regions 110 may include a first shot region 112 and a second shot region 114 adjacent to each other. The photolithography process may be performed independently for each shot region 110. The circuit pattern may be transferred onto the entire wafer 100 as the shot process repeats. Each shot region 110 may be defined in a fixed size and shape. For example, the shot region 110 may have a rectangular or square shape, although other shapes may be used.

Depending on the characteristics of the photolithography device, one shot region may be divided into two (or more) shot regions, and conversely, two (or more) shot regions may be processed as one shot region. For example, the first shot region 112 and the second shot region 114 may be processed as one shot region in some photolithography devices (e.g., Low-Numerical Aperture Extreme Ultraviolet (Low-NA EUV) equipment), but may be processed as two separate shot regions in high-resolution photolithography devices (e.g., High-NA EUV). In the present disclosure, an example in which the first shot region 112 and the second shot region 114 are processed as individual shot regions will be mainly described.

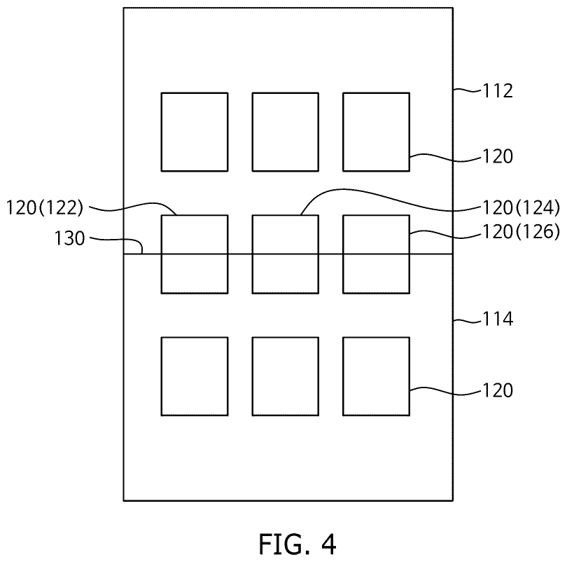

FIG. 4 is an enlarged view of the first shot region 112 and the second shot region 114 of FIG. 3.

The wafer (e.g., 100 in FIG. 3) may include a plurality of dies. Referring to FIG. 4, a plurality of dies 120 may be arranged in each of the shot regions 112 and 114 of the wafer. In one or more example embodiments, the plurality of dies 120 may include a first die 122, a second die 124, and a third die 126. The first to third dies 122, 124, and 126 may be disposed across a shot boundary line 130 between two shot regions, that is, the first shot region 112 and the second shot region 114. That is, the first to third dies 122, 124, and 126 disposed along the shot boundary line 130 may be arranged across both the first shot region 112 and the second shot region 114.

Although not shown, each of the first to third dies 122, 124, and 126 may include a circuit pattern. In one or more example embodiments, layout patterns associated with each of the first to third dies 122, 124, and 126 may be provided in the form of individual layout pattern data. That is, the first die 122 may be associated with a first layout, and the second die 124 may be associated with a second layout. Similarly, the third die 126 may be associated with a third layout. The first to third layouts may include the same layout pattern, but are not limited thereto, and may include different layout patterns according to design. The associated layout has been described above with reference to the example of the die disposed on the shot boundary line 130, but this example may be applicable to all or some of the plurality of dies 120.

In one or more example embodiments, in order to increase the layout transfer accuracy in the shot boundary line 130, a plurality of pieces of layout pattern data corresponding to a plurality of dies 122, 124, and 126 associated with the shot boundary line 130 may be merged so that the OPC operation and the SRAF application may be processed in batch. Hereinafter, a mask data preparation method according to one or more example embodiments will be described in detail.

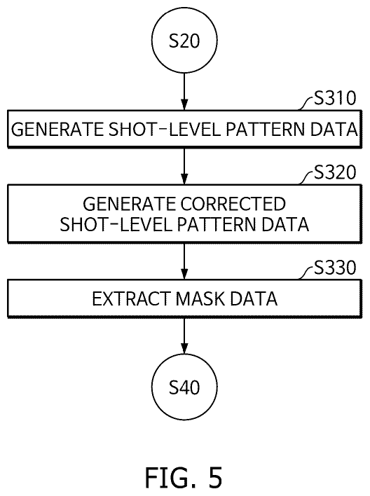

FIG. 5 is a flowchart provided to explain an operation S40 of FIG. 2 in detail. FIGS. 6 to 13 are diagrams illustrating an example of a process in which operations of S310, S320, and S330 of FIG. 5 are performed.

Referring to FIG. 5, the mask data preparation method may include the operation S310 of merging a plurality of pieces of layout pattern data sharing the shot boundary line (e.g., 130 of FIG. 4) to generate shot-level pattern data.

FIG. 6 is a diagram illustrating an example of first layout pattern data LD1 and second layout pattern data LD2 according to some example embodiments. Each of the layout pattern data LD1 and LD2 may include information related to the layout pattern included in each of the plurality of dies (e.g., 120 of FIG. 3) described with reference to FIGS. 3 and 4.

Referring to FIG. 6, the first layout pattern data LD1 and the second layout pattern data LD2 may be provided. The first layout pattern data LD1 and the second layout pattern data LD2 may be design layout data. For convenience of explanation, the first layout pattern data LD1 and the second layout pattern data LD2 associated with each of two dies (e.g., 122, 124) of the plurality of dies will be described as an example. The first layout pattern data LD1 may include a first die region DR1. The first die region DR1 may correspond to an outline of the first die (e.g., 122), and may include information on the shape and position of the outline of the first die. The second layout pattern data LD2 may include a second die region DR2. The second die region DR2 may correspond to an outline of the second die (e.g., 124) and may include information on the shape and position of the outline of the second die.

The first layout pattern data LD1 and the second layout pattern data LD2 may share the boundary line. The first layout pattern data LD1 may include a first layout L1. In addition, the second layout pattern data LD2 may include a second layout L2. Specifically, the first layout L1 and the second layout L2 may correspond to the layout pattern to be transferred across a shot boundary line (e.g., 130 in FIG. 4) between two adjacent shot regions (e.g., 112 and 114 in FIG. 4) on the actual wafer.

The first layout pattern data LD1 and the second layout pattern data LD2 may be provided as separate data. For example, the position information of the first layout L1 may be defined based on a first reference point RP1. For example, the contour position information of the first layout L1 may be expressed as a relative coordinate value with respect to the first reference point RP1. Similarly, the position information of the second layout L2 may be defined based on a second reference point RP2. For example, the contour position information of the second layout L2 may be expressed as a relative coordinate value with respect to the second reference point RP2.

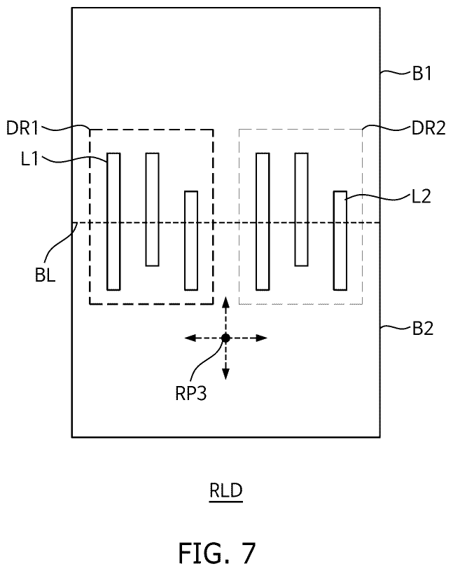

FIG. 7 is a diagram illustrating an example of shot-level pattern data RLD according to some example embodiments. Referring to FIG. 7, the first layout pattern data (e.g., LD1 of FIG. 6) and the second layout pattern data (e.g., LD2 of FIG. 6) may be merged to generate shot-level pattern data RLD.

The shot-level pattern data RLD may include a first shot-data region B1 and a second shot-data region B2. The first shot-data region B1 may be a data region corresponding to the first shot region (e.g., 112 of FIG. 4) of the actual wafer. Further, the second shot-data region B2 may be a data region corresponding to the second shot region (e.g., 114 in FIG. 4). The first shot-data region B1 and the second shot-data region B2 may be adjacent to each other. A boundary line BL may be formed between the first shot-data region B1 and the second shot-data region B2. The boundary line BL may correspond to the shot boundary line (e.g., 130 of FIG. 4) of the actual wafer.

The first layout pattern data LD1 and the second layout pattern data LD2 may be merged based on a new reference point of the shot-level pattern data RLD. For example, the shot-level pattern data RLD may be generated by rearranging the position information of the first layout L1 and the second layout L2, based on a third reference point RP3, using relative position information between the position information of the first layout L1 based on the first reference point (e.g., RP1 of FIG. 6) and the position information of the second layout L2 based on the second reference point (e.g., RP2 of FIG. 6). The third reference point RP3 may correspond to a center point of the second shot-data region B2. However, the disclosure is not limited thereto. For example, the third reference point RP3 may correspond to a center point of the first shot-data region B1 or a center point of the second shot-data region B2.

Referring back to FIG. 5, the mask data manufacturing method may include performing the OPC operation and the SRAF operation based on the shot-level pattern data to generate corrected shot-level pattern data, at S320. Specifically, based on the shot-level pattern data, a first correction layout and a first plurality of auxiliary patterns associated with the first layout may be generated, and a second correction layout and a second plurality of auxiliary patterns associated with the second layout may be generated, to generate corrected shot-level pattern data.

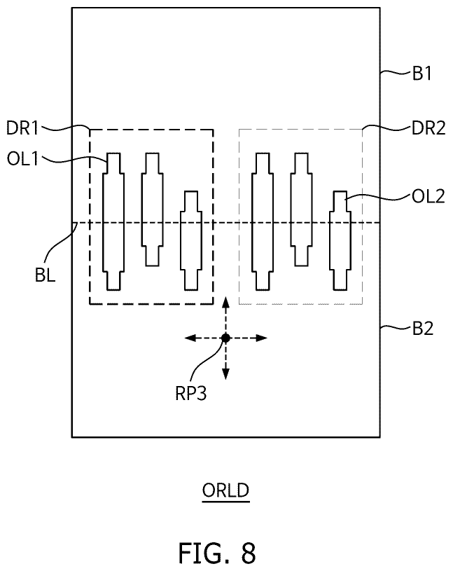

FIG. 8 is a diagram illustrating an example of shot-level pattern data ORLD subjected to the OPC operation according to some example embodiments. Referring to FIG. 8, a first correction layout OL1 may be generated by performing the OPC operation based on the first layout (e.g., L1 in FIG. 7). Similarly, a second correction layout OL2 may be generated by performing the OPC operation based on the second layout (e.g., L2 in FIG. 7). The form of each of the first correction layout OL1 and the second correction layout OL2 is an example, and the layouts may be formed in any suitable form by the OPC operation.

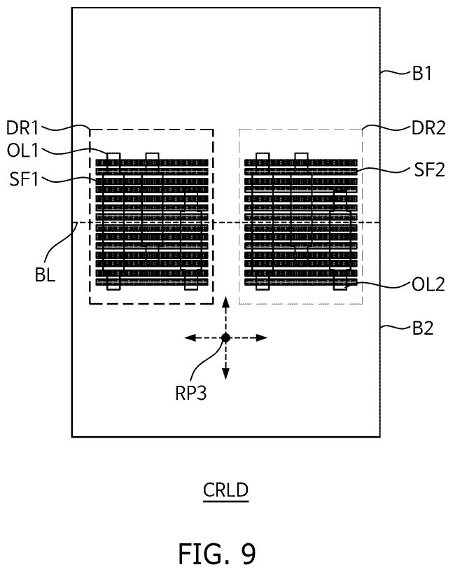

FIG. 9 is a diagram illustrating an example of corrected shot-level pattern data CRLD subjected to the SRAF operation according to some example embodiments.

Referring to FIG. 9, a first plurality of auxiliary patterns SF1 may be generated by performing the SRAF operation based on the first correction layout OL1. Similarly, a second plurality of auxiliary patterns SF2 may be generated by performing the SRAF operation based on the second correction layout OL2. The plurality of auxiliary patterns SF1 and SF2 may be at positions (e.g., optimal or improved positions) based on the overall shape, size, spacing, etc. of the correction layouts OL1 and OL2.

In one or more example embodiments, the first plurality of auxiliary patterns SF1 may be generated in overlap with the first correction layout OL1, and the second plurality of auxiliary patterns SF2 may be generated in overlap with the second correction layout OL2. The overlapping state may be maintained until the corrected shot-level pattern data is divided into two pieces of mask data. As will be described in detail below, this is possible because, in the process of dividing the corrected shot-level pattern data into two pieces of mask data, only a part of the first plurality of auxiliary patterns SF1 and the first correction layout OL1 are extracted so as not to overlap each other, and only a part of the second plurality of auxiliary patterns SF2 and the second correction layout OL2 are extracted so as not to overlap each other.

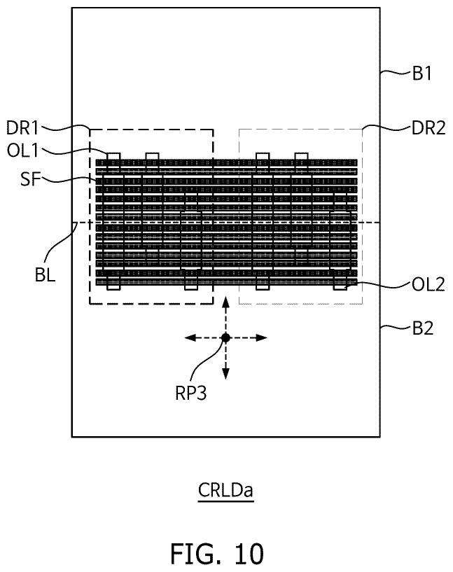

FIG. 10 is a diagram illustrating an example of corrected shot-level pattern data CRLDa according to some example embodiments. In one or more example embodiments, the first plurality of auxiliary patterns SF1 and the second plurality of auxiliary patterns SF2 may be the same auxiliary pattern. That is, a plurality of auxiliary patterns SF may be generated based on both the first correction layout OL1 and the second correction layout OL2. Referring to FIG. 10, a plurality of auxiliary patterns SF may be generated in overlap with both the first correction layout OL1 and the second correction layout OL2.

Referring to FIG. 5 again, the mask data preparation method may include extracting (S330) the mask data based on the corrected shot-level pattern data. Specifically, the first mask data may be extracted based on the corrected shot-level pattern data. Similarly, the second mask data associated with the second shot region may be extracted.

Hereinafter, for convenience of explanation, the corrected shot-level pattern data CRLD of FIG. 9 will be mainly described.

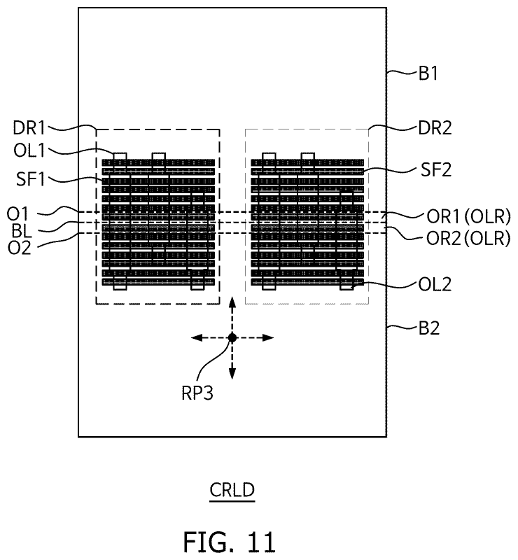

FIG. 11 is a diagram illustrating an example of corrected shot-level pattern data CRLD including an overlapping region OLD according to some example embodiments.

Referring to FIG. 11, an overlapping region OLR between the first shot-data region B1 and the second shot-data region B2 may be determined based on the corrected shot-level pattern data CRLD. Specifically, a first overlapping outline O1 spaced apart from the boundary line BL toward the first shot-data region B1 may be determined. In addition, a second overlapping outline O2 spaced apart from the boundary line BL toward the second shot-data region B2 may be determined. Accordingly, an overlapping region OLR may be defined by the first overlapping outline O1 and the second overlapping outline O2. The overlapping region OLR may include a first partial overlapping region OR1 defined by the boundary line BL and the first overlapping outline O1, and a second partial overlapping region OR2 defined by the boundary line BL and the second overlapping outline O2.

The boundary line BL and the overlapping outlines O1 and O2 may be spaced apart by a predetermined (or, alternatively, selected, or desired) distance. The predetermined (or, alternatively, selected, or desired) distance may be determined in consideration of various factors such as the shape, position, spacing of the layout, and/or processing process that uses the photolithography device.

A distance between the boundary line BL and the first overlapping outline O1 and a distance between the boundary line BL and the second overlapping outline O2 may be determined to be the same. However, the disclosure is not limited thereto. Depending on designs, the distance between the boundary line BL and the first overlapping outline O1 and the distance between the boundary line BL and the second overlapping outline O2 may be determined differently.

FIG. 11 illustrates an example in which the overlapping region OLR is determined based on the corrected shot-level pattern data CRLD, but the disclosure is not limited thereto. For example, the overlapping region OLR may be determined based on at least one of the shot-level pattern data (e.g., RLD in FIG. 7) and the corrected shot-level pattern data CRLD.

FIG. 12 is a diagram illustrating an example of first mask data MD1 according to some example embodiments.

Referring to FIG. 12, the first mask data MD1 may be generated based on the corrected shot-level pattern data (e.g., CRLD of FIG. 11). Specifically, the first mask data MD1 may be generated by extracting a part of the correction layout and a part of the auxiliary pattern from the corrected shot-level pattern data. The first mask data MD1 may include a first partial correction layout L1_T, a second partial correction layout L2_T, a first partial auxiliary pattern SF1_T, and a second partial auxiliary pattern SF2_T.

Specifically, the first partial correction layout L1_T and the second partial correction layout L2_T on the side of the first shot-data region B1 may be extracted and included in the first mask data MD1. For example, as a part of the first correction layout (e.g., OL1 in FIG. 11), the first partial correction layout L1_T located inside each of the first shot-data region B1 and the second partial overlapping region OR2 may be extracted. Similarly, as a part of the second correction layout (e.g., OL2 in FIG. 11), the second partial correction layout L2_T located inside each of the first shot-data region B1 and the second partial overlapping region OR2 may be extracted. That is, the first partial correction layout L1_T and the second partial correction layout L2_T may be formed by connecting the layout pattern in the first shot-data region B1 and the layout pattern in the second partial overlapping region OR2.

In addition, the first partial auxiliary pattern SF1_T and the second partial auxiliary pattern SF2_T on the side of the second shot-data region B2 may be extracted and included in the first mask data MD1. For example, from the first plurality of auxiliary patterns (e.g., SF1 of FIG. 11), a first partial auxiliary pattern SF1_T, which is located in the remaining region excluding the second partial overlapping region OR2 in the second shot-data region B2, may be extracted. Similarly, from the second plurality of auxiliary patterns (e.g., SF2 of FIG. 11), a second partial auxiliary pattern SF2_T, which is located in the remaining region excluding the second partial overlapping region OR2 in the second shot-data region B2, may be extracted.

As a result, mask data in which the layout and the auxiliary pattern do not overlap each other may be generated. For example, the first partial correction layout L1_T and the first partial auxiliary pattern SF1_T may not overlap each other. Further, the second partial correction layout L2_T and the second partial auxiliary pattern SF2_T may not overlap each other.

In one or more example embodiments, position information of each of the first partial correction layout L1_T, the second partial correction layout L2_T, the first partial auxiliary pattern SF1_T, and the second partial auxiliary pattern SF2_T may be realigned based on a fourth reference point RP4 associated with the first shot-data region B1.

FIG. 13 is a diagram illustrating an example of second mask data MD2 according to some example embodiments.

Referring to FIG. 13, the second mask data MD2 may be generated based on the corrected shot-level pattern data (e.g., CRLD of FIG. 11). Specifically, the second mask data MD2 may be generated by extracting a part of the correction layout and a part of the auxiliary pattern from the corrected shot-level pattern data. The second mask data MD2 may include a third partial correction layout L1_B, a fourth partial correction layout L2_B, a third partial auxiliary pattern SF1_B, and a fourth partial auxiliary pattern SF2_B.

Specifically, the third partial correction layout L1_B and the fourth partial correction layout L2_B on the side of the second shot-data region B2 may be extracted and included in the second mask data MD2. For example, as a part of the first correction layout (e.g., OL1 in FIG. 11), the third partial correction layout L1_B, which is located inside each of the second shot-data region B2 and the first partial overlapping region OR1, may be extracted. Similarly, as a part of the second correction layout (e.g., OL2 of FIG. 11), the fourth partial correction layout L2_B, which is located inside each of the second shot-data region B2 and the first partial overlapping region OR1, may be extracted. That is, each of the third partial correction layout L1_B and the fourth partial correction layout L2_B may be formed by connecting a layout pattern in the second shot-data region B2 and a layout pattern in the first partial overlapping region OR1.

In addition, the third partial auxiliary pattern SF1_B and the fourth partial auxiliary pattern SF2_B on the side of the second shot-data region B2 may be extracted and included in the second mask data MD2. For example, from the first plurality of auxiliary patterns (e.g., SF1 of FIG. 11), a third partial auxiliary pattern SF1_B, which is located in the remaining region excluding the first partial overlapping region OR1 in the first shot-data region B1, may be extracted. Similarly, from the second plurality of auxiliary patterns (e.g., SF2 of FIG. 11), a fourth partial auxiliary pattern SF2_B, which is located in the remaining region excluding the first partial overlapping region OR1 in the first shot-data region B1, may be extracted.

As a result, mask data in which the layout and the auxiliary pattern do not overlap each other may be generated. For example, the third partial correction layout L1_B and the third partial auxiliary pattern SF1_B may not overlap each other. Further, the fourth partial correction layout L2_B and the fourth partial auxiliary pattern SF2_B may not overlap each other.

In one or more example embodiments, position information of each of the third partial correction layout L1_B, the fourth partial correction layout L2_B, the third partial auxiliary pattern SF1_B, and the fourth partial auxiliary pattern SF2_B may be realigned based on a fifth reference point RP5 associated with the second shot-data region B2.

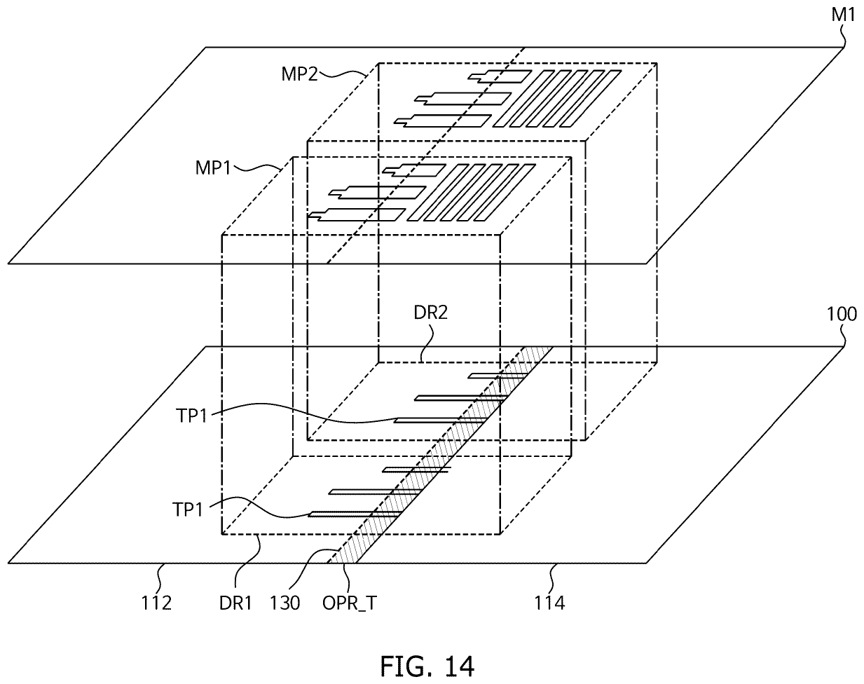

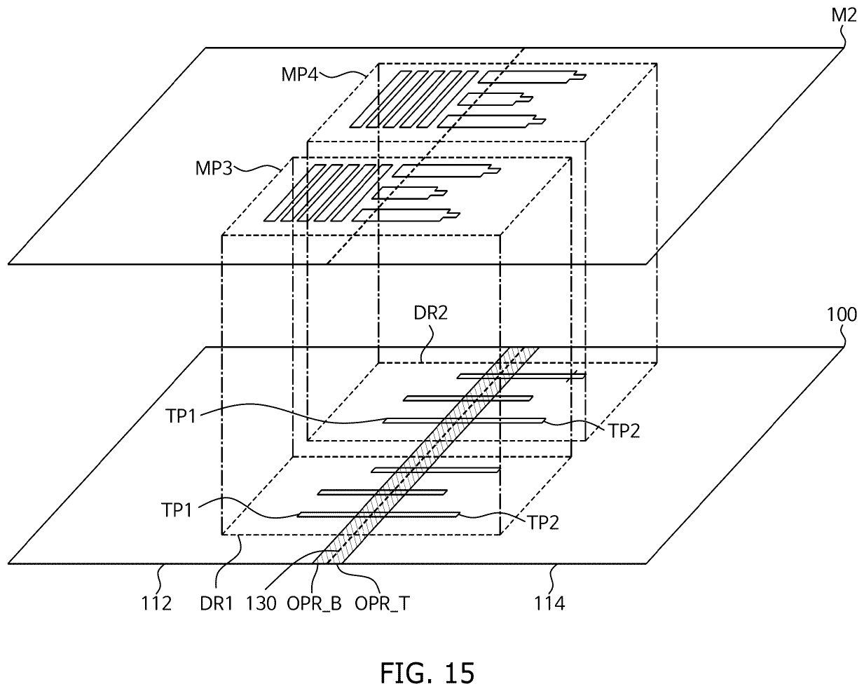

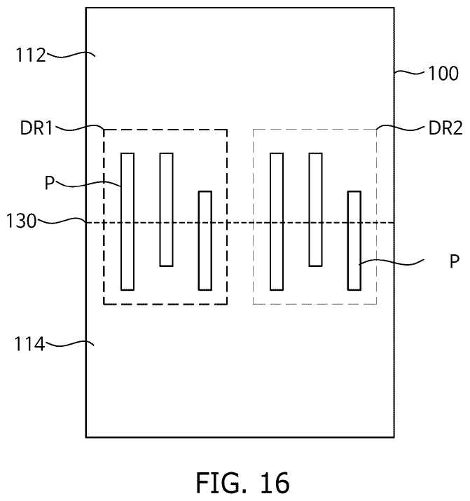

FIGS. 14 and 15 are diagrams provided to explain a process of transferring the circuit pattern onto the wafer 100 using a first mask M1 and a second mask M2 according to some example embodiments. FIG. 16 is a diagram illustrating an example of the circuit pattern transferred onto the wafer 100 according to some example embodiments.

Referring to FIGS. 14 and 15, the first mask M1 and the second mask M2 may be used to perform photolithography process with respect to the first shot region 112 and the second shot region 114 on the wafer 100. A first partial transfer pattern TP1 may be formed on the wafer 100 using the first mask M1, and a second partial transfer pattern TP2 may be formed on the wafer 100 using the second mask M2. Each of the first partial transfer pattern TP1 and the second partial transfer pattern TP2 may be formed in overlap with each other on the wafer 100.

The first partial transfer pattern TP1 may include circuit patterns of the first die 122 and the second die 124. The first die 122 and the second die 124 may be positioned across the shot boundary line 130 between the first shot region 112 and the second shot region 114. That is, the first mask M1 and the second mask M2 may be used to transfer the circuit patterns of a plurality of dies (e.g., 120 of FIG. 4) across the shot boundary line 130.

The first mask M1 may be used to transfer the circuit pattern on the first shot region 112 and the first transfer overlapping region OPR_T, and the first partial transfer pattern TP1 may be formed in this process. The first partial transfer pattern TP1 may be formed on the entire first shot region 112 and in the first transfer overlapping region OPR_T located in the second shot region 114.

The second mask M2 may be used as a mask for transferring the circuit pattern on the second shot region 114 and the second transfer overlapping region OPR_B, and the second partial transfer pattern TP2 may be formed in this process. The second partial transfer pattern TP2 may be formed on the entire second shot region 114 and in the second transfer overlapping region OPR_B located in the first shot region 112. The first transfer overlapping region OPR_T and the second transfer overlapping region OPR_B may indicate a region in which two mask patterns MP1 and MP2 are transferred in overlap each other.

The first mask M1 is a mask manufactured based on the first mask data (e.g., MD1 of FIG. 12), and may include the first mask pattern MP1 and the second mask pattern MP2. The first mask pattern MP1 may correspond to the first partial correction layout (e.g., L1_T in FIG. 12) and the first partial auxiliary pattern (e.g., SF1_T in FIG. 12). In addition, the second mask pattern MP2 may correspond to the second partial correction layout (e.g., L2_T in FIG. 12) and the second partial auxiliary pattern (e.g., SF2_T in FIG. 12).

The second mask M2 may be a mask manufactured based on the second mask data (e.g., MD2 of FIG. 13), and may include a third mask pattern MP3 and a fourth mask pattern MP4. The third mask pattern MP3 may correspond to the third partial correction layout (e.g., L1_B in FIG. 13) and the third partial auxiliary pattern (e.g., SF1_B in FIG. 13). In addition, the fourth mask pattern MP4 may correspond to the fourth partial correction layout (e.g., L2_B in FIG. 13) and the fourth partial auxiliary pattern (e.g., SF2_B in FIG. 13).

The partial auxiliary patterns SF1_T, SF2_T, SF1_B, and SF2_B of each of the masks M1 and M2 may be used to increase the accuracy of the transfer process and may not be actually transferred on the wafer 100.

In one or more example embodiments, the process of forming a circuit pattern P on the wafer 100 may be performed using the High-NA EUV equipment. For example, the first partial transfer pattern TP1 and the second partial transfer pattern TP2 may be formed using the High-NA EUV equipment. However, the disclosure is not limited thereto.

As described above, the circuit pattern P may be formed across the first shot region 112 and the second shot region 114 of the wafer 100. Referring to FIG. 16, the circuit pattern P may be formed on the first shot region 112 and the second shot region 114 of the wafer 100. The circuit pattern P may correspond to the shape of the design layout (e.g., L1 and L2 of FIGS. 6 and 7).

According to example embodiments of the present disclosure, in the mask data preparation process, a plurality of pieces of die layout pattern data including design layout pattern data sharing the shot boundary line 130 may be merged so that the OPC operation and the SRAF application may be processed in batch. Through this, the continuity of the layout pattern at the boundary line may be improved and/or ensured, and/or the transfer accuracy may be improved. Further, according to some example embodiments, there may be an increase in reliability, operating parameters (e.g., temperature), speed, accuracy, and/or power efficiency of the device based on the above methods. Therefore, the improved devices and methods overcome the deficiencies of the conventional devices and methods while reducing resource consumption, and/or improving data accuracy, operating parameters, and resource allocation (e.g., latency). Further, there is an improvement in user experience and the method of production of the mask and/or semiconductor chip manufacturing methods (for example, in relation to High-NA EUV lithography) by providing the improved process.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Example embodiments of the disclosure are not limited by those described above and accompanying drawings, and various forms of substitutions, modifications, and variations will be possible by those of ordinary skill in the art that falls within the scope not departing from the technical idea, which will also fall within the scope.

1. A mask data preparation method, comprising:
generating shot-level pattern data including a first layout and a second layout, the first layout and the second layout located across a boundary line between a first shot-data region and a second shot-data region adjacent to the first shot-data region;
generating a first correction layout and a first plurality of auxiliary patterns associated with the first layout based on the shot-level pattern data;
generating a second correction layout and a second plurality of auxiliary patterns associated with the second layout based on the shot-level pattern data;
generating corrected shot-level pattern data based on the first correction layout, the first plurality of auxiliary patterns, the second correction layout, and the second plurality of auxiliary patterns;
extracting a first mask data based on the corrected shot-level pattern data; and
extracting a second mask data based on the corrected shot-level pattern data.

2. The method according to claim 1, wherein the generating the shot-level pattern data includes rearranging position information of the first layout and the second layout, based on a third reference point, using relative position information between position information of the first layout based on a first reference point and position information of the second layout based on a second reference point.

3. The method according to claim 2, wherein the third reference point corresponds to a center point of the first shot-data region or a center point of the second shot-data region.

4. The method according to claim 1, wherein the generating the corrected shot-level pattern data includes:
based on the first correction layout, generating the first plurality of auxiliary patterns; and
based on the second correction layout, generating the second plurality of auxiliary patterns.

5. The method according to claim 1, wherein
the first plurality of auxiliary patterns overlap the first correction layout, and
the second plurality of auxiliary patterns overlap the second correction layout.

6. The method according to claim 1, further comprising, based on at least one of the shot-level pattern data and the corrected shot-level pattern data, determining an overlapping region,
wherein
the determining the overlapping region includes:
determining a first overlapping outline spaced apart from the boundary line toward the first shot-data region;
determining a second overlapping outline spaced apart from the boundary line toward the second shot-data region; and
determining an overlapping region defined by the first overlapping outline and the second overlapping outline, and
the overlapping region includes a first partial overlapping region defined by the boundary line and the first overlapping outline, and a second partial overlapping region defined by the boundary line and the second overlapping outline.

7. The method according to claim 6, wherein the extracting the first mask data includes:
extracting, as a part of the first correction layout, a first partial correction layout inside each of the first shot-data region and the second partial overlapping region;
extracting, as a part of the second correction layout, a second partial correction layout inside each of the first shot-data region and the second partial overlapping region;
extracting a first partial auxiliary pattern from the first plurality of auxiliary patterns in a remaining region excluding the second partial overlapping region in the second shot-data region; and
extracting a second partial auxiliary pattern from the second plurality of auxiliary patterns in a remaining region excluding the second partial overlapping region in the second shot-data region.

8. The method according to claim 7, wherein the extracting the first mask data further includes rearranging position information of each of the first partial correction layout, the second partial correction layout, the first partial auxiliary pattern, and the second partial auxiliary pattern based on a fourth reference point associated with the first shot-data region.

9. The method according to claim 6, wherein the extracting the second mask data includes:
extracting, as a part of the first correction layout, a third partial correction layout inside each of the second shot-data region and the first partial overlapping region;
extracting, as a part of the second correction layout, a fourth partial correction layout inside each of the second shot-data region and the first partial overlapping region;
extracting a third partial auxiliary pattern from the first plurality of auxiliary patterns in a remaining region excluding the first partial overlapping region in the first shot-data region; and
extracting a fourth partial auxiliary pattern from the second plurality of auxiliary patterns in a remaining region excluding the first partial overlapping region in the first shot-data region.

10. The method according to claim 9, wherein extracting the second mask data further includes rearranging position information of each of the third partial correction layout, the fourth partial correction layout, the third partial auxiliary pattern, and the fourth partial auxiliary pattern based on a fifth reference point associated with the second shot-data region.

11. A semiconductor chip manufacturing method, comprising:
generating shot-level pattern data including a first layout and a second layout, the first layout and the second layout on a boundary line between a first shot-data region and a second shot-data region adjacent to the first shot-data region;
generating a first correction layout and a first plurality of auxiliary patterns associated with the first layout based on the shot-level pattern data;
generating a second correction layout and a second plurality of auxiliary patterns associated with the second layout based on the shot-level pattern data;
generating corrected shot-level pattern data based on the first correction layout, the first plurality of auxiliary patterns, the second correction layout, and the second plurality of auxiliary patterns;
extracting a first mask data based on the corrected shot-level pattern data;
extracting a second mask data based on the corrected shot-level pattern data;
manufacturing a first mask based on the first mask data;
manufacturing a second mask based on the second mask data;
forming a first partial transfer pattern on a wafer using the first mask; and
forming a second partial transfer pattern on the wafer using the second mask.

12. The method according to claim 11, wherein each of the first partial transfer pattern and the second partial transfer pattern are formed on the wafer in overlap with each other.

13. The method according to claim 11, wherein
the corrected shot-level pattern data includes an overlapping region defined by a first overlapping outline and a second overlapping outline,
the first overlapping outline is spaced apart from the boundary line toward the first shot-data region,
the second overlapping outline is spaced apart from the boundary line toward the second shot-data region, and
the overlapping region includes a first partial overlapping region defined by the boundary line and the first overlapping outline, and a second partial overlapping region defined by the boundary line and the second overlapping outline.

14. The method according to claim 13, wherein the first mask data includes:
as a part of the first correction layout, a first partial correction layout included in the first shot-data region and the second partial overlapping region;
as a part of the second correction layout, a second partial correction layout included in the first shot-data region and the second partial overlapping region;
a first partial auxiliary pattern, from the first plurality of auxiliary patterns, in a remaining region excluding the second partial overlapping region in the second shot-data region; and
a second partial auxiliary pattern, from the second plurality of auxiliary patterns, in a remaining region excluding the second partial overlapping region in the second shot-data region.

15. The method according to claim 14, wherein
the first mask includes a first mask pattern and a second mask pattern,
the first mask pattern includes a pattern corresponding to the first partial correction layout and the first partial auxiliary pattern, and
the second mask pattern includes a pattern corresponding to the second partial correction layout and the second partial auxiliary pattern.

16. The method according to claim 13, wherein the second mask data further includes:
as a part of the first correction layout, a third partial correction layout included in the second shot-data region and the first partial overlapping region;
as a part of the second correction layout, a fourth partial correction layout included in the second shot-data region and the first partial overlapping region;
a third partial auxiliary pattern, from the first plurality of auxiliary patterns, in a remaining region excluding the first partial overlapping region in the first shot-data region; and
a fourth partial auxiliary pattern, from the second plurality of auxiliary patterns, in a remaining region excluding the first partial overlapping region in the first shot-data region.

17. The method according to claim 16, wherein
the second mask includes a third mask pattern and a fourth mask pattern,
the third mask pattern includes a pattern corresponding to the third partial correction layout and the third partial auxiliary pattern, and
the fourth mask pattern includes a pattern corresponding to the fourth partial correction layout and the fourth partial auxiliary pattern.

18. The method according to claim 11, wherein
the wafer includes a plurality of dies,
the plurality of dies includes a first die and a second die that is different from the first die,
the first die is associated with the first layout, and
the second die is associated with the second layout.

19. The method according to claim 11, wherein the first partial transfer pattern and the second partial transfer pattern are formed using High-NA EUV equipment.

20. A computing device that performs mask data preparation, comprising:
a non-transitory memory configured to store at least one instruction; and
a processor including a plurality of processing cores, wherein the processor is configured to execute the at least one instruction to:
generate shot-level pattern data including a first layout and a second layout, the first layout and the second layout located across a boundary line between a first shot-data region and a second shot-data region adjacent to the first shot-data region;
generate a first correction layout and a first plurality of auxiliary patterns associated with the first layout based on the shot-level pattern data;
generate a second correction layout and a second plurality of auxiliary patterns associated with the second layout based on the shot-level pattern data;
generate corrected shot-level pattern data based on the first correction layout, the first plurality of auxiliary patterns, the second correction layout, and the second plurality of auxiliary patterns;
extract a first mask data based on the corrected shot-level pattern data; and
extract a second mask data based on the corrected shot-level pattern data.
